(19) United States
(12) Patent Application Publication
(10) Pub. No.: US 2025/0040110 A1
(43) Pub. Date: Jan. 30, 2025

(54) BATTERY DISCONNECT UNIT AND DRIVE SYSTEM

(71) Applicant: Robert Bosch GmbH, Stuttgart (DE)

(72) Inventors: Roman Marx, Moensheim (DE); Markus Schmitt, Tamm (DE)

(21) Appl. No.: 18/782,383

(22) Filed: Jul. 24, 2024

(30) Foreign Application Priority Data
Jul. 24, 2023 (DE) 10 2023 207 006.5

(51) Int. Cl. H05K 7/20; H01L 23/46; H01M 50/574

(52) U.S. Cl. CPC H05K 7/20927; H01M 50/574; H01L 23/46; H05K 7/20254; H05K 7/20272

(57) ABSTRACT

A battery disconnect unit for disconnecting a battery arrangement from at least one consumer of a drive system. The battery disconnect unit includes a cooling device having a cooling channel, through which a dielectric fluid flows from a cooling channel inlet to a cooling channel outlet of the cooling channel. The cooling channel includes a base plate and at least one component of a power electronics system. The at least one component of the power electronics system is arranged in the cooling channel, and the dielectric fluid flows over the at least one component via at least one ceramic substrate on the base plate of the cooling device.

### BACKGROUND

The invention relates to a battery disconnect unit and a drive system.

According to the prior art, a battery disconnect unit (BDU) is used to switch the battery of an electric vehicle on and off, depending on the operating status. In this context, the three BDU configurations specified are usually used:
1. fuse and relay
2. pyro fuse and relay
3. fuse, pyro fuse, and relay.

When using a combination of a relay and a circuit by means of a SiC-based semiconductor on AMB components for a BDU, active cooling of these components is necessary because these semiconductors achieve high heat flux densities and the associated temperatures due to their compact design. AMB stands for Active Metal Brazing, and the building block is a ceramic substrate that is connected directly to a base plate, e.g. a cooling plate, by means of a soldered joint. Cooling is, e.g., achieved using a cooling plate, through which a coolant flows. According to the prior art, a cooling plate made of aluminum sheets in a brazing process can be used in this case. Depending on the requirements with regard to the currents being switched and the power losses in the form of heat, these cooling plates can be equipped with an additional water fin (internal insert) to increase the cooling capacity. In this case, the AMB components are soldered onto the cooling plate in order to achieve an optimum thermal transition from the AMB component to the cooling plate via the water fin into the cooling fluid.

This not only places high demands on the choice of internal inserts, but also on the volumetric flow of the cooling fluid and its maximum permissible temperature. The aim is to cool the semiconductors effectively and to ensure that the temperature distribution of the individual chips is as homogeneous as possible.

These requirements mean that cooling plates with a relatively high pressure loss are used in this type of cooling concept. In combination with the required high volumetric flow, this leads to additional cooling systems with high pump capacities. These not only consume a lot of energy, but also lead to higher costs and vehicle weight due to their dimensions.

The chips are usually encapsulated to prevent leakage currents and short circuits between the closely spaced electrical conductors. Additional components such as a limiting frame and the casting compound are required in this case, which incurs additional costs.

### SUMMARY

The above problem is solved by a battery disconnect unit and by a drive system having the features of the disclosure. Further features and details of the invention arise from the description and the drawings. Features and details that are described in connection with the battery disconnect unit according to the invention naturally also apply in connection with the drive system according to the invention, and vice versa, so that with regard to the disclosure, reference is or can always be made to the individual aspects of the invention reciprocally.

A first aspect of the invention is a battery disconnect unit for separating a battery arrangement from at least one consumer of a drive system, said unit comprising a cooling device having a cooling channel, through which a dielectric fluid flows from a cooling channel inlet to a cooling channel outlet of the cooling channel, whereby the cooling channel comprises a base plate and at least one component, in particular a plurality of components, of a power electronics means, whereby the at least one component of the power electronics means is arranged in the cooling channel, and the dielectric fluid flows over the component via at least one ceramic substrate on the base plate of the cooling device.

The at least one component of the power electronics means, e.g. a SiC chip, is arranged on the at least one ceramic substrate. A large number of components can in this case also be arranged on a ceramic substrate. It is also conceivable that multiple ceramic substrates are provided, each comprising at least one component or multiple components.

The cooling device can be connected to a closed cooling circuit, so that the dielectric fluid can be introduced from the cooling circuit via the cooling channel inlet and discharged via the cooling channel outlet.

The flow over of the components (or the at least one component) of the power electronics means is particularly advantageous because said at least one component of the power electronics means generates a high heat flux density in a very small space, which must be dissipated.

This heat is partially dissipated via the ceramic substrate into the base plate and then to the outside. However, most of the heat is dissipated by the dielectric via the flow against the components of the power electronics means. Due to the direct flow against at least one component of the power electronics means, no additional thermal resistances arise, as is the case in the prior art. Instead, smaller temperature differences occur between the heat source and the dielectric fluid. The flow over the component ensures that the heat generated is dissipated evenly and efficiently so that the components (or the at least one component) of the power electronics means can be cooled quickly and easily.

The cooling channel inlet, via which the dielectric fluid enters, is arranged at a distance from the area of the at least one component of the power electronics means, opposite to the direction of flow, in order to develop sufficient flow development for flow over the component. The cooling channel outlet is arranged at a distance from the area of the at least one component of the power electronics means in the direction of flow.

In the context of the invention, it can be advantageous for the cooling device to have a cooling plate arranged opposite the base plate.

The cooling plate is arranged opposite the base plate, in particular geometrically opposite, whereby these are arranged at a distance from each other. To form the flow channel, at least two opposing side walls are provided, which are arranged between the cooling plate and the base plate.

When flow takes place over the base plate and the cooling plate of the cooling device of the battery disconnect unit, the heat of the at least one component of the power electronics means is dissipated and cooled at the same time such that the dielectric is always at a constant temperature, so the temperature gradient required to dissipate the heat flux density of the at least one component of the power electronics means is provided.

Within the scope of the invention, it is conceivable that a flow structure for deflecting the flow of the dielectric fluid is provided in the cooling channel of the cooling device, whereby the flow structure is designed to deflect the flow of the dielectric fluid such that the fluid flows directly against at least one component of the power electronics means.

On the one hand, the flow can be deflected and guided by means of the flow structure so that the main part of the flow is deflected directly onto the at least one component or the multitude of components of the power electronics means. At the same time, the turbulence of the flow against the component can be increased by means of the flow structure. The increase in turbulence, or the regular breaking up of the boundary layer so that it remains turbulent, leads to efficient heat dissipation. Furthermore, it is possible to use the flow structure not only to generate and direct the flow against the components, but also to introduce additional turbulence in order to improve the cross-exchange of heat or dielectric fluid in the flow. A variety of geometries can in this case be used for the flow structure.

Within the scope of the invention, it can be provided that the flow structure can be connected to the cooling plate and/or to at least two side walls of the cooling channel of the cooling device, and/or whereby the flow structure can be integrated into the cooling plate, or whereby the flow structure and the cooling plate are monolithic.

The flow structure can be a single new component in the manner of an insert, which can be easily connected to the cooling plate or the at least two side walls of the battery disconnect unit. In this case, it is conceivable that the flow structure can be welded, glued, screwed, or clipped on.

It is also conceivable that the flow structure designed to be integral, i.e., that both the flow structure and the cooling plate and or the at least two side walls of the cooling channel of the cooling device are designed such that the flow structure can be easily mounted in it, e.g. by placing it on top or inserting it.

Both the connection to the cooling plate and/or the side walls and the integration into these can be easily created and flexibly designed at the same time. In these designs, it is conceivable that the flow structure be exchanged. In this case, it is therefore possible to vary the arrangement of the components on the ceramic substrate because the flow structure can also be adapted or replaced accordingly.

At the same time, it is conceivable that the cooling plate and the flow structure are shaped monolithically, whereby the cooling plate then provides the outer structure of the flow structure for deflecting the flow.

Monolithic production, i.e. a cooling plate comprising the flow structure, is simple to manufacture and easy to handle.

It is also conceivable that the flow structure is designed to be wave-shaped or sawtooth-shaped.

These shapes have proven to be particularly advantageous for deflecting the flow, as well as for generating a cross-flow.

It is also conceivable that the flow structure is a separator plate, whereby the separator plate is arranged in the cooling channel in order to divide the cooling channel and to deflect the flow of the dielectric fluid.

For this purpose, a third side wall is also arranged between the base plate and the cooling plate, whereby the third side wall is arranged orthogonally to the at least two side walls (not shown). The separator plate and the third side wall are arranged at a distance from each other and form a deflection area so that the dielectric, as the dielectric fluid, enters at the cooling channel inlet as an outward flow between the base plate and the separator plate and flows against the power electronics means in a parallel arrangement in order to cool them homogeneously at the same fluid temperature. The flowing dielectric is then deflected by 180° in the deflection area, then flows back between the separator plate and the cooling plate to the cooling channel outlet. The outward flow and the return flow are parallel to each other and flow counter to one another.

It is also conceivable that the at least one ceramic substrate comprises a recess such that at least one secondary cooling channel is provided below the at least one power electronics means component arranged on it.

The formation of a secondary cooling channel enables flushing of the components or at least one component of the power electronics from beneath. It is also conceivable that multiple recesses be provided under the at least one component such that multiple secondary cooling channels are formed.

This is particularly advantageous if the heat flux densities are very high because the heat can be dissipated quickly and easily, both from the top of the at least one component and from the underside of the at least one component.

Furthermore, it can be provided within the scope of the invention that the cooling plate comprises at least two, preferably a plurality of, cooling fins on an inner surface facing the cooling channel and/or an outer surface facing away from the cooling channel.

By means of the cooling fins on the inner surface facing the cooling channel or the outer surface facing away from the cooling channel, an additional increase in surface area can be generated, via which the heat can be dissipated. At the same time, it is conceivable that the cooling plate's outer surface comprising the at least two cooling fins be additionally cooled in order to cool the dielectric so that as much heat as possible can be dissipated from the power electronics components.

With regard to the present invention, it is conceivable that the cooling plate can be connected to a cooling unit of the consumer or the battery arrangement, or that air cooling and/or liquid cooling is provided.

As previously mentioned hereinabove, the cooling device is a closed cooling circuit. This circuit can be connected to a cooling unit of the consumer or the battery arrangement, so no further cooling circuit is required. This is particularly efficient and cost-effective.

However, it is also conceivable that liquid cooling be provided, which is an additional cooling unit, into which the cooling device is integrated.

Within the scope of the invention, it is conceivable that the cooling device be connected to an external cooling unit.

The cooling unit can in this case be a heat exchanger. A closed circuit for the dielectric fluid is in this case provided in order to cool the dielectric fluid in the cooling unit.

It is also conceivable that the base plate and/or the cooling plate be made of a thermally conductive material, in particular aluminum.

The use of a heat-conducting material, in particular aluminum, is particularly advantageous because heat can already be partially dissipated via the base or base plate.

Within the scope of the invention, it is optionally possible for a copper layer, in particular a cold-sprayed copper layer, to be provided between the base plate and the ceramic substrate.

The use of a copper layer to connect the ceramic substrate to the base plate is particularly advantageous because both a thermal and a mechanical connection can be achieved quickly and efficiently. The ceramic substrate comprising the at least one component is connected in a bonded manner to the copper layer on the base plate in a soldering process. As a result, a very effective thermal transition from the ceramic substrate to the base plate is achieved.

In the context of the invention, it can be advantageous for the dielectric fluid to have a viscosity from 0.5 mPas to 1000 mPas, preferably 0.5 mPas to 100 mPas.

The dielectric fluid is a fluid that is not electrically conductive. Dielectric fluids can also have an increased viscosity in the range of between 1 mPas and 1000 mPas. The viscosity can in this case change briefly due to the heating of the dielectric fluid. At the same time, it should be ensured that a certain viscosity be present in order to be able to generate a uniform flow. Dielectric fluids with a viscosity of 0.5-100 mPas are preferred because these values can ensure a uniform flow and effective absorption of the heat flux density.

Within the scope of the invention, it is conceivable that the dielectric fluid have a heat capacity from 0.8 to 4 kJ/kgK, preferably from 1.0 to 2.5 kJ/kgK.

Dielectric fluids with an increased heat capacity can absorb and dissipate more heat. Accordingly, dielectric fluids with a heat capacity from 1.0 to 2.5 kJ/kgK ensure that the heat generated is dissipated quickly and efficiently.

Within the scope of the invention, a battery interface can be provided for electrical connection to the battery arrangement, and a consumer interface provided for electrical connection to the consumer.

The battery interface and the consumer interface are particularly advantageous for simple connection to a battery unit or the consumer of a drive system. These consumer interfaces, or rather the battery interface, can be provided for the control and regulation of the battery disconnect unit or the battery unit and the consumer by means of the battery disconnect unit. However, a data-communicating consumer interface or battery interface that transmits certain data (e.g., the temperature or the flow rate of the dielectric fluid) to a control unit is also conceivable.

A second aspect of the invention is a drive system according to the invention comprising a battery arrangement, a consumer, and a battery disconnect unit according to the first aspect of the invention, whereby the battery arrangement and the battery disconnect unit are electronically connected to each other via the battery interface and whereby the consumer and the battery disconnect unit are electronically connected to each other via the consumer interface.

The drive system comprises the battery disconnect unit described hereinabove and the advantages thereof.

Advantages described in detail for the battery disconnect unit according to the first aspect of the invention also apply to the drive system according to the second aspect of the invention, and vice versa.

Further advantages, features, and details of the invention follow from the description hereinafter, in which several exemplary embodiments of the invention are described in detail with reference to the drawings. In this context, the features mentioned in the claims and in the description can each be essential to the invention individually or in any combination. The invention is illustrated in the following drawings:

### BRIEF DESCRIPTION OF THE DRAWINGS

FIG. 1 is a schematic representation of a first exemplary embodiment of a battery disconnect unit according to the invention,

FIG. 2 is a schematic representation of a second exemplary embodiment of a battery disconnect unit according to the invention,

FIG. 3 is a schematic representation of a third exemplary embodiment of a battery disconnect unit according to the invention,

FIG. 4 is a schematic representation of a drive system according to the invention.

### DETAILED DESCRIPTION

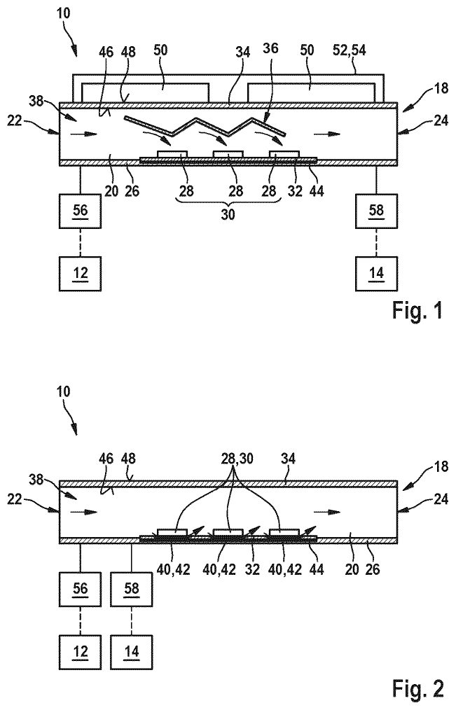

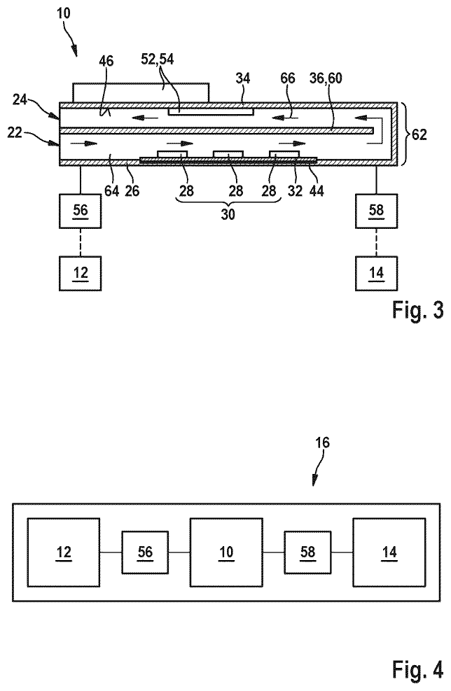

FIG. 1, FIG. 2, and FIG. 3 each show a battery disconnect unit 10 for disconnecting a battery arrangement 12 from at least one consumer 14 of a drive system 16. The battery disconnect unit comprises a cooling device 18 having a cooling channel 20, through which a dielectric fluid flows from a cooling channel inlet 22 to a cooling channel outlet 24 of the cooling channel 20, and at least one component 28 of a power electronics means 30.

The cooling channel 20 comprises a base plate 26 and a cooling plate 34 arranged opposite the base plate 26.

In this case, the at least one component 28 of the power electronics means 30 is arranged in the cooling channel 20, and dielectric fluid flows over the component via at least one ceramic substrate 32 on the base plate 26 of the cooling device 18.

The first exemplary embodiment according to FIG. 1 provides a flow structure 36 in the cooling channel 20 of the cooling device 18 for deflecting the flow of the dielectric fluid, as indicated by the arrows in FIG. 1. The flow structure 36 is sawtooth-shaped and designed and arranged above the at least one component of the power electronics means to deflect the flow of the dielectric fluid such that the fluid flows directly against at least one component 28 of the power electronics means 30.

The flow structure 36 is in this case connected to the at least two side walls 38 of the cooling channel 20 of the cooling device 18.

It is also conceivable that the flow structure be connectable to the cooling plate 34.

The flow structure 36 can be integrated into the cooling plate 34 or manufactured monolithically with the cooling plate 34.

The cooling plate of FIG. 1 is connected to a liquid cooling system, and flow takes place against an outer surface 48 facing away from the cooling channel 20. Connection to an air cooling system is also conceivable in this case. At least two cooling fins 50 are provided on the outer surface 48 to increase the surface area for cooling or dissipating heat from the cooling channel 20. It is also conceivable that cooling fins 50 be provided on the inside.

The cooling fins can be continuous along the direction of flow or, as shown, interrupted along the outer surface. Multiple ribs can in this case also be arranged parallel to each other.

In the battery disconnect unit according to FIG. 2, the at least one ceramic substrate 32 comprises a recess 40 such that at least one secondary cooling channel 42 is provided below the at least one component 28 of the power electronics means 30 arranged thereon.

In the present case, such recesses 40 are provided under each component 28 of the power electronics means 30.

In FIG. 3, the flow structure 36 is a separator plate 60, whereby the separator plate 60 is arranged in the cooling channel 20 to divide the cooling channel 20 and to deflect the flow of the dielectric fluid.

For this purpose, a third side wall 38 is additionally arranged between the base plate 26 and the cooling plate 34, whereby the third side wall 38 is arranged orthogonally to the at least two side walls (not shown). The separator plate 60 and the third side wall 38 are arranged at a distance from each other and form a deflection area 62 such that the dielectric, as the dielectric fluid, enters at the cooling channel inlet 22 as an outward flow 64 between the base plate 26 and the separator plate 60 and flows against the power electronics means 30 in a parallel arrangement in order to cool it homogeneously at the same fluid temperature. The flowing dielectric is then deflected by 180° in the deflection area 62 and flows as a return flow 66 between the separator plate 60 and the cooling plate 34 to the cooling channel outlet 24. The outward flow 64 and the return flow 66 are parallel to each other and flow in counter to one another.

In the exemplary embodiment in FIG. 1, as well as in FIG. 2 and FIG. 3, both the base plate 26 and the cooling plate 34 are made of a heat-conducting material, in this case aluminum. A copper layer 44, in particular a cold-sprayed copper layer 44, is provided for attaching the ceramic substrate 32 to the base plate. This layer is used to solder the ceramic substrate to the base plate.

The dielectric fluid used in this case has a viscosity from 0.5 mPas 20° C. to 1000 mPas 20° C. and a heat capacity from 0.8 to 4 kJ/kgK.

Furthermore, a battery interface 56 for electrical connection to the battery arrangement 12 and a consumer interface 58 for electrical connection to the consumer 14 are provided in both exemplary embodiments.

FIG. 4 shows a drive system 16 comprising a battery arrangement 12, a consumer 14, and a battery disconnect unit 10, as shown in FIG. 1 or FIG. 2. The battery arrangement 12 and the battery disconnect unit 10 are in this case electronically connected to each other via the battery interface 56, and the consumer 14 and the battery disconnect unit 10 are electronically connected to each other via the consumer interface 58.

1. A battery disconnect unit (10) for disconnecting a battery arrangement (12) from at least one consumer (14) of a drive system (16), said battery disconnect unit comprising:
a cooling device (18) having a cooling channel (20), through which a dielectric fluid flows from a cooling channel inlet (22) to a cooling channel outlet (24) of the cooling channel (20), wherein the cooling channel (20) comprises a base plate (26),
at least one component (28) of a power electronics means (30),
wherein the at least one component (28) of the power electronics means (30) is arranged in the cooling channel (20), and the dielectric fluid flows over the component via at least one ceramic substrate (32) on the base plate (26) of the cooling device (18).

2. The battery disconnect unit (10) according to claim 1, wherein the cooling device (18) comprises a cooling plate (34) arranged opposite the base plate (26).

3. The battery disconnect unit (10) according to claim 1, wherein a flow structure (36) for deflecting the flow of the dielectric fluid is provided in the cooling channel (20) of the cooling device (18), wherein the flow structure (36) is configured to deflect the flow of the dielectric fluid such that the dielectric fluid flows directly against at least one component (28) of the power electronics means (30).

4. The battery disconnect unit (10) according to claim 3, wherein
the flow structure (36) can be connected to the cooling plate (34) and/or to at least two side walls (38) of the cooling channel (20) of the cooling device (18), and/or
wherein the flow structure (36) can be integrated into the cooling plate (34), or
wherein the flow structure (36) and the cooling plate (34) are monolithic.

5. The battery disconnect unit (10) according to claim 3, wherein the flow structure (36) is configured to be wave-shaped or sawtooth-shaped.

6. The battery disconnect unit (10) according to claim 1, wherein the at least one ceramic substrate (32) comprises a recess (40) such that at least one secondary cooling channel (42) is provided below the at least one component (28) of the power electronics means (30) arranged thereon.

7. The battery disconnect unit (10) according to claim 2, wherein the cooling plate (34) comprises at least two cooling fins (50) on an inner surface (46) facing the cooling channel (20) and/or an outer surface (48) facing away from the cooling channel (20).

8. The battery disconnect unit (10) according to claim 2, wherein the cooling plate (34) can be connected to a cooling unit (52) of the consumer (14) or the battery, or that air or liquid cooling (54) is provided.

9. The battery disconnect unit (10) according to claim 2, wherein the base plate (26) and/or the cooling plate (34) are made of a thermally conductive material.

10. The battery disconnect unit (10) according to claim 1, wherein a copper layer (44) is provided between the base plate (26) and the ceramic substrate (32).

11. The battery disconnect unit (10) according to claim 1, wherein the dielectric fluid has a viscosity from 0.5 mPas (20° C.) to 1000 mPas (20° C.).

12. The battery disconnect unit (10) according to claim 1, wherein the dielectric fluid has a heat capacity from 0.8 to 4 kJ/kgK.

13. The battery disconnect unit (10) according to claim 1, wherein a battery interface (56) is provided for electrical connection to the battery arrangement (12), and a consumer interface (58) is provided for electrical connection to the consumer (14).

14. A drive system (16) comprising a battery arrangement (12), a consumer (14), and a battery disconnect unit (10) according to claim 1, wherein the battery arrangement (12) and the battery disconnect unit (10) are electronically connected to each other via the battery interface (56), and wherein the consumer (14) and the battery disconnect unit (10) are electronically connected to each other via the consumer interface (58).

15. The battery disconnect unit (10) according to claim 1, wherein the power electronics means (30) includes a plurality of components (28).

16. The battery disconnect unit (10) according to claim 9, wherein the base plate (26) and/or the cooling plate (34) are made of aluminum.

17. The battery disconnect unit (10) according to claim 10, wherein the copper layer (44) is a cold-sprayed copper layer (44).

18. The battery disconnect unit (10) according to claim 11, wherein the dielectric fluid has a viscosity from 0.5 mPas (20° C.) to 100 mPas (20° C.).

19. The battery disconnect unit (10) according to claim 12, wherein the dielectric fluid has a heat capacity from 1.0 to 2.5 kJ/kgK.
